(19) United States
(12) Patent Application Publication
(10) Pub. No.: US 2007/0205716 A1
(43) Pub. Date: Sep. 6, 2007

(54) HOLE INJECTION STRUCTURE OF ORGANIC ELECTROLUMINESCENCE DEVICE AND METHOD FOR MANUFACTURING THE SAME

(76) Inventors: Chin-Hsin Chen, Taipei City (TW); Shih-Feng Hsu, Taoyuan County (TW); Hsiao-Wen Huang, Tainan County (TW); Shi-Hao Li, Taipei County (TW); Chung-Chun Lee, Yun-Lin County (TW)

Correspondence Address: NORTH AMERICA INTELLECTUAL PROPERTY CORPORATION, P.O. BOX 506, MERRIFIELD, VA, 22116, US

(21) Appl. No.: 11/427,330

(22) Filed: Jun. 28, 2006

(30) Foreign Application Priority Data
Mar. 3, 2006 (TW) 095107283

(51) Int. Cl. H01L 51/54; H01L 51/52

(52) U.S. Cl. 313/506; 428/690; 428/917; 257/40; 257/E51.026

(57) ABSTRACT

An organic electroluminescence device has at least one anode disposed on a substrate, at least one hole injection structure including at least one first material layer and at least one second material layer disposed on the anode, at least one organic luminescence layer disposed on the hole injection structure, and an electron source layer disposed on the organic luminescence layer. The first material layer includes a mixture of at least one first conductive material and at least one organic material, and the second material layer includes at least one second conductive material.

### BACKGROUND OF THE INVENTION

1. Field of the Invention

The present invention relates to an organic electroluminescence device and a method for manufacturing the same, and particularly, to an organic electroluminescence device that may reduce driving voltage and the method for manufacturing the same.

2. Description of the Prior Art

Flat displays have advantages of saving electricity, low radiation, and small size over the traditional cathode ray tube (CRT) displays. For these reasons, flat displays are replacing CRT displays gradually. With the improvements of flat display techniques, the price of flat displays is getting lower. Therefore, flat displays are more popular and undergoing developments for larger sizes. The organic electroluminescence display is a most remarkable product among the flat displays at present.

Referring to FIG. 1, FIG. 1 schematically illustrates a conventional organic electroluminescence device. As shown in FIG. 1, the conventional organic electroluminescence device comprises an anode 12 disposed on a substrate 10, a cathode 14 disposed upon the anode 12, and an organic luminescence layer 16 disposed between the anode 12 and the cathode 14. In addition, the conventional organic electroluminescence device also comprises a hole injection layer 18 and a hole transport layer 20 disposed between the anode 12 and the organic luminescence layer 16, and an electron injection layer 22 and an electron transport layer 24 disposed between the organic luminescence layer 16 and the cathode 14.

The principle of the organic electroluminescence device is explained as follows. While a bias is formed between the anode 12 and the cathode 14, holes will pass by the hole injection layer 18 and the hole transport layer 20 and enter the organic luminescence layer 16. For the same reason, electrons will also pass the electron injection layer 22 and the electron transport layer 24 and enter the organic luminescence layer 16. The recombination of holes and electrons will form excitons in the organic luminescence layer 16. These excitons will release energy and return to the ground state. Meanwhile, a part of the energy may be released as different colors of light depending on the material of the organic electroluminescence layer 16 and result in luminescence.

For the organic electroluminescence device, the function of the hole injection layer 18 is to reduce driving voltage, and further to reduce the energy barrier between the anode 12 and the hole transportation layer 20. This may improve the luminescence efficiency. In general, the hole injection layer 18 is made of a single organic material layer, such as NPB, or a single metal oxide layer. This may restrict the application, especially when the interface of the anode 12 and the hole transport layer 20 has large variant work function. The hole injection layer 18 merely reduces the driving voltage and results in life shortening of the organic electroluminescence device, or low efficiency of luminescence.

### SUMMARY OF THE INVENTION

It is therefore a primary objective of the present invention to provide a hole injection structure of an organic electroluminescence device to reduce driving voltage thereof and a method for manufacturing the same.

The present invention discloses an organic electroluminescence device comprising at least one anode disposed on a substrate, at least one hole injection structure having at least one first material layer and at least one second material layer disposed on the anode, at least one organic luminescence layer disposed on the hole injection layer, and at least one electron source layer disposed on the organic luminescence layer. In addition, the first material layer comprises a mixture of at least one first conductive material and at least one organic material, and the second material layer comprises at least one second conductive material.

The present invention also discloses a method for manufacturing an organic electroluminescence device. The method comprises steps of forming at least one anode on a substrate. Then, the following steps comprise forming at least one hole injection structure on the anode, wherein the hole injection structure comprises at least one first material layer and at least one second material layer. The first material layer further comprises a mixture of at least one first conductive material and at least one organic material. The second material layer comprises at least one second conductive material. Afterward, the steps of the method comprise forming at least one organic luminescence layer on the hole injection structure, and forming at least one electron source layer on the organic luminescence layer.

The present invention further discloses a hole injection structure comprising at least one first material layer and at least one second material layer. The first material layer comprises a mixture of at least one first conductive material and at least one organic material, and the second material layer comprises at least one second conductive material.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 schematically illustrates an organic electroluminescence device of the prior art.

FIG. 2 to FIG. 4 schematically illustrates a method for manufacturing an organic electroluminescence device according to a preferred embodiment of the present invention.

FIG. 5 illustrates a voltage and current density plot of the organic electroluminescence device.

FIG. 6 to FIG. 8 schematically illustrates a concentration plot of the first material layer according to another preferred embodiment of the present invention.

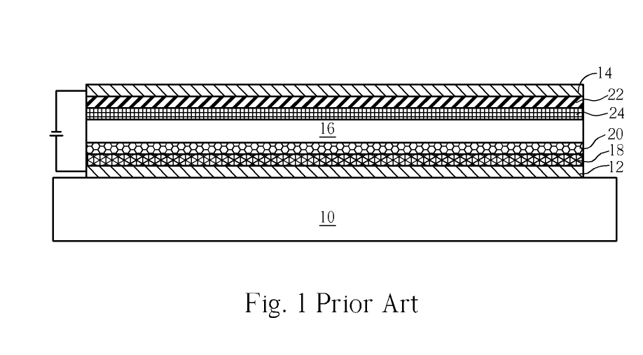

### DETAILED DESCRIPTION

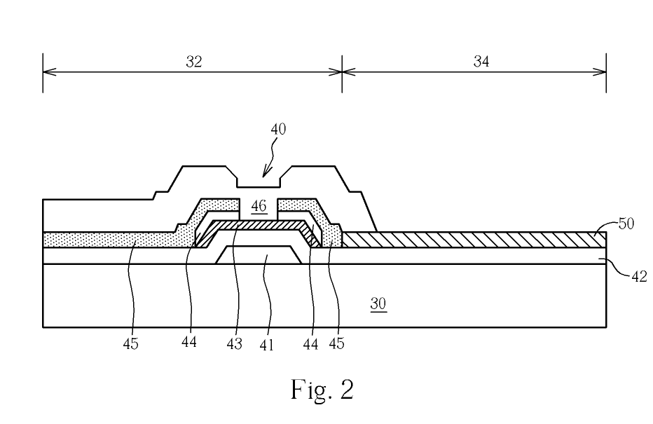

Referring to FIG. 2 through FIG. 4, FIG. 2 through FIG. 4 schematically illustrates a method for manufacturing an organic electroluminescence device according to a preferred embodiment of the present invention. As shown in FIG. 2, a substrate 30 having a device area 32 and a display area 34 is provided. An active matrix organic light emitting diode (AMOLED) panel is selected to illustrate the present embodiment of the invention. Therefore, a thin film transistor (TFT) array is disposed on the substrate 30. However, if the organic electroluminescence device is applied to an organic light emitting diode display panel, the TFT array is dispensable so that a scanning electrode controls organic electroluminescence device. To emphasize the characteristic of the present invention, FIG. 2 only shows one TFT 40 electrically connected to the organic electroluminescence device. The TFT 40 includes a gate 41, a dielectric layer 42 formed on the gate 41, a semiconductor layer 43 covered the dielectric layer 42, a dopant amorphous silicon layer 44 formed on the semiconductor layer 43 aside the gate 41, and a source/drain 45 formed on the dopant amorphous silicon layer 44. In the present embodiment, the TFT 40 is a bottom gate TFT. However, the TFT 40 may be a top gate TFT or like as. In addition, the semiconductor layer 43 may be a polysilicon layer, an amorphous silicon layer, a micro-crystal silicon layer, a single-crystal silicon layer, or combinations thereof. The substrate 30 may comprise transparent material, such as glass, quartz, or like as; opaque material, such as ceramic, semiconductor materials, or like as; or flexible material, such as plastics or like as.

Afterward, at least one anode 50 is formed on the dielectric layer 42 in the display area 34, and the anode 50 is electrically connected to the source/drain 45 of the TFT 40. The material of the anode 50 is AlNd alloy having a work function of about 3.8 eV. Other material for the anode 50 is also allowable. Thereafter, a passivation layer 46 is formed on the source/drain 45.

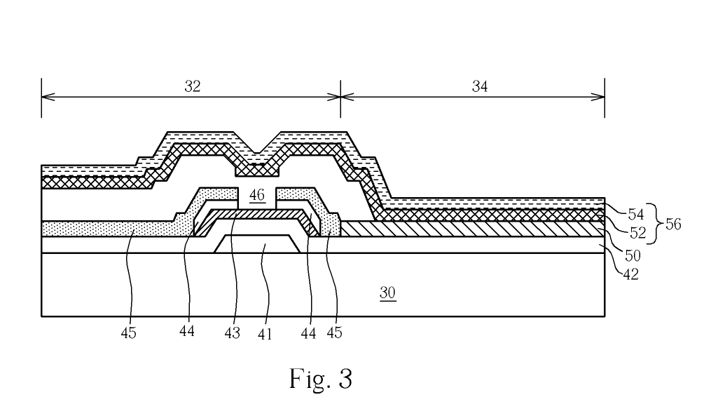

As shown in FIG. 3, at least one first material layer 52 is formed on the anode 50. The first material layer 52 comprises a mixture of at least one first conductive material and at least one organic material. In the present invention, the first conductive material comprises silver having a work function of about 4.7 eV, and the organic material comprises N,N′-bis-(1-naphtyl)-N,N′-diphenyl-1,1′-biphenyl-4,4′-diamine (NPB). The mixture comprises silver with concentration ranging from about 1% to about 10%, and with concentration of about 5% is preferred. Therefore, the mixture comprises the organic material with concentration ranging from about 90% to about 99%, with concentration of about 95% being preferred. Furthermore, the mixture of the first conductive material and the organic material has a substantially uniform concentration, and other types of mixture are allowable. The first conductive material may be selected from other metals, such as nickel, gold, platinum, or other metals or alloys having a work function of more than 4 eV. The organic material may be polyethylene dioxythiophene/polystyrene sulfonate (PEDOT:PSS), 4,4′,4″-tris(3-methylphenylphenylamino) triphenylamine (m-MTDATA), or polyabuline. Thereafter, at least one second material layer 54 is formed on the first material layer 52. The second material layer 54 comprises at least one second conductive material. In the present invention, the second conductive material comprises tungsten oxide having a work function of about 5.2 eV. The second conductive material may be praseodymium oxide, vanadium oxide, molybdenum oxide, other metal, or combinations thereof. The first material layer 52 and the second material layer 54 form a hole injection layer 56 of the present embodiment.

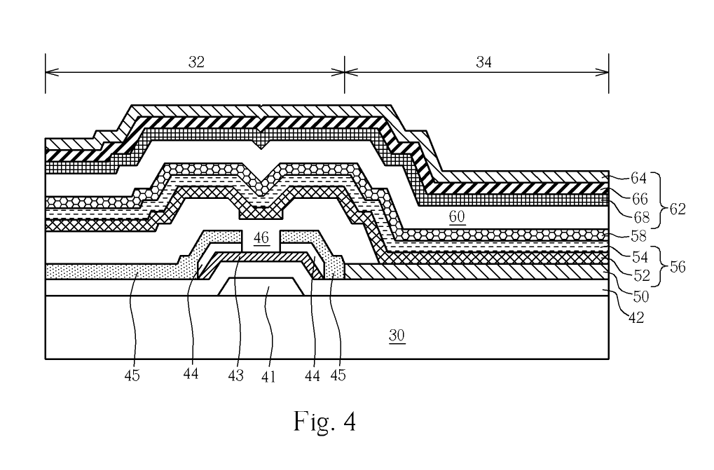

As shown in FIG. 4, at least one hole transport layer 58, at least one organic luminescence layer 60, and at least one electron source layer 62 are formed on the second material layer 54. Therefore, an organic electroluminescence device is formed. The electron source layer 62 comprises at least one cathode 64 and at least one electron transport layer 68, and further comprises at least one electron injection layer 66 disposed between the cathode 64 and the electron transport layer 68. Moreover, the material of the hole transport layer 58, the organic luminescence layer 60, the electron injection layer 66, and the cathode 64 may be any suitable substance. For instance, the hole injection layer 58 can use NPB as material, the electron transport layer 62 can use Alq, and the organic luminescence layer 60 can use any organic luminescence material or polymer luminescence material.

The above-mentioned hole injection structure 56 of the organic electroluminescence device includes the first material layer 52 comprising metal and organic material and the second material layer 54 comprising metal oxide to reduce driving voltage. However, the hole injection structure 56 may include other substances. According to a preferred embodiment of the present invention, the first conductive material of the first material layer 52 is tungsten oxide, and the organic material is NPB. In addition, the second conductive material of the second material layer 54 also uses tungsten oxide as material. The mixture of tungsten oxide and NPB comprises tungsten oxide with concentration ranging from about 1% to about 99%, with concentration ranging from about 10% to about 30% being preferred. Therefore, the mixture of tungsten oxide and NPB comprises NPB with concentration ranging from about 99% to about 1%, with preferred concentration ranging from about 90% to about 70%. In the present embodiment, the mixture of tungsten oxide and NPB has a substantially uniform concentration and other kinds of mixtures are allowable. Moreover, the first conductive material may comprise praseodymium oxide, vanadium oxide, molybdenum oxide, other metal, or a mixture of metal and metal oxide thereof. An organic material other than NPB may also be selected. Furthermore, the second material may comprise praseodymium oxide, vanadium oxide, molybdenum oxide, other metal, or a mixture of metal and metal oxide thereof.

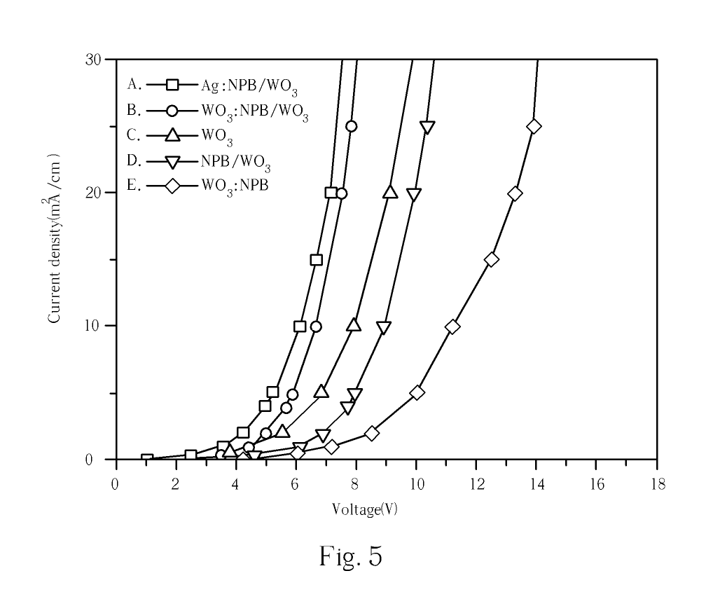

The organic electroluminescence device according to two preferred embodiments of the present invention is illustrated as follows. Referring to FIG. 5, FIG. 5 schematically illustrates a plot of voltage and current density of the organic electroluminescence device according to the present invention. FIG. 5 shows the relationship between voltage and current density according to five different hole injection structures A to E. In this experiment, the materials of the anode and the hole transport layer are AlNd alloy and NPB, respectively. The organic luminescence layer comprises Alq, and the electron transport layer comprises CsCO₃ and Alq. The electron injection layer 66 comprises LiF and the cathode 64 comprises silver. In addition, sample A is a hole injection structure of the first embodiment comprising a mixture of silver and NPB as the first material layer that has a uniform concentration and tungsten oxide as the second material layer. Sample B is a hole injection structure of the second embodiment comprising a mixture of tungsten oxide and NPB as the first material layer that has a uniform concentration and tungsten oxide as second material layer. Additionally, sample C to sample E are controls, wherein the hole injection structure of sample C comprises tungsten oxide only. The hole injection layer of sample D comprises NPB only as the first material layer and tungsten oxide only as the second material. The hole injection structure of sample E comprises a mixture of tungsten oxide and NPB. As shown in FIG. 5, hole injection structure s according to the embodiment of the present invention, samples A and B, reduce driving voltage of the organic electroluminescence device effectively. However, other hole injection structures, samples C, D and E, have a higher driving voltage than that of the hole injection structure according to the present invention.

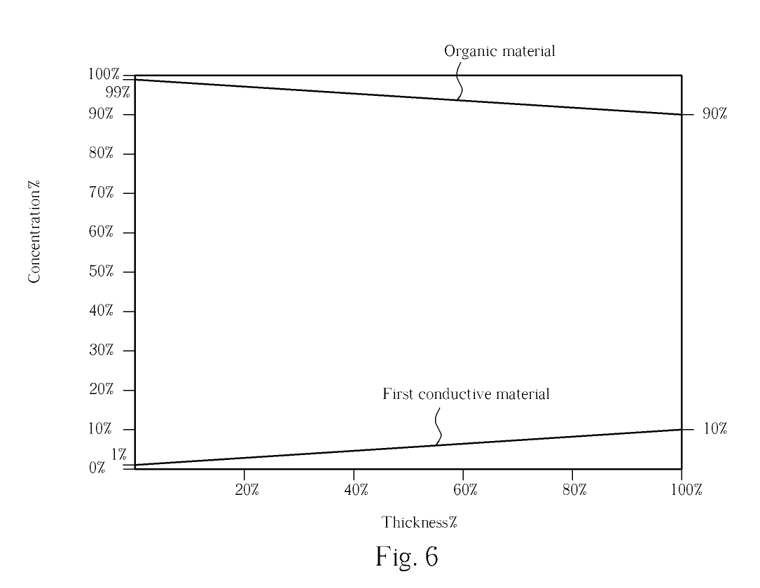

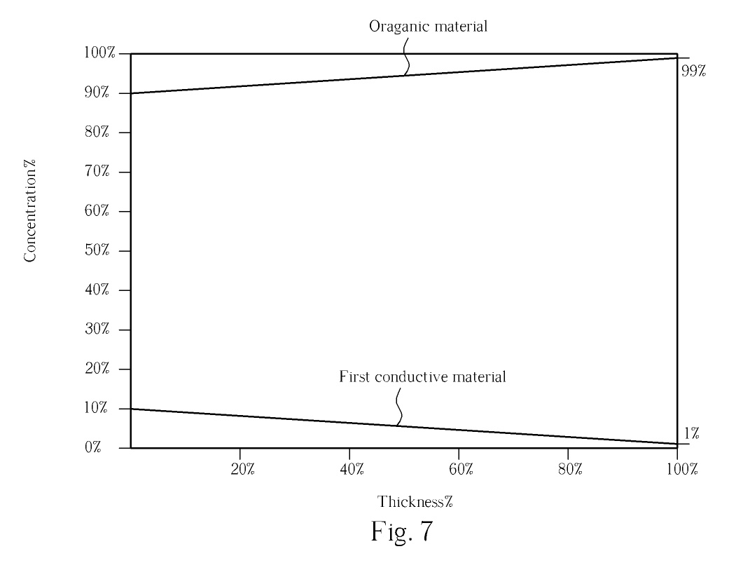

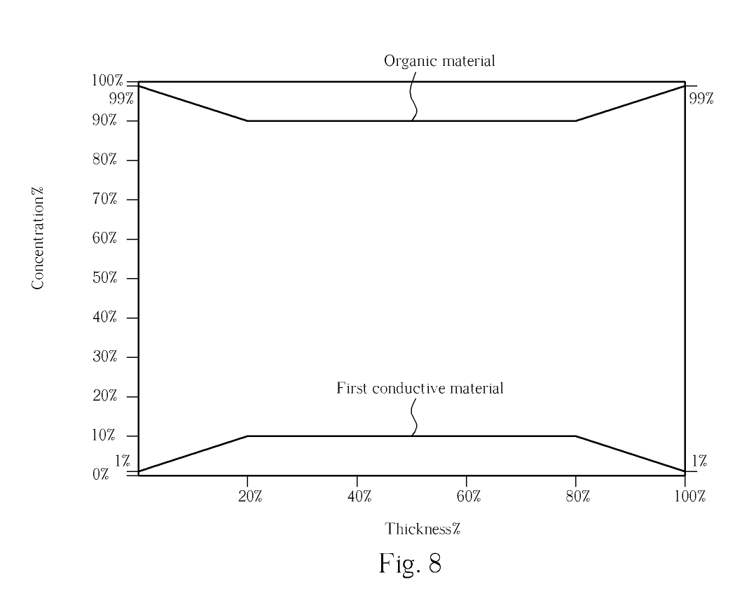

The previous embodiments take a mixture of the first conductive material and the organic material having a substantially uniform concentration as the material of the first material layer to emphasize the characteristic and effect of the present invention. The composition of the first material layer may have different concentrations, such as a mixture of the first material and the organic material having a concentration with a spatial distribution. Referring to FIG. 6 to FIG. 8, FIG. 6 to FIG. 8 schematically illustrates a concentration plot of the first material layer according to another embodiment of the present invention. The horizontal axis represents the thickness of the first material layer in percentage, and the vertical axis represents the concentration of the first conductive material or the organic material in percentage. As shown in FIG. 6, the first material layer comprises the first conductive material with concentration ranging from about 1% to about 10% and increases gradually. The first material layer comprises the organic material with concentration ranging from about 90% to about 99% and decreases progressively. As shown in FIG. 7, the first material layer comprises the first conductive material with concentration ranging from about 1% to about 10% and decreases gradually. The first material layer comprises the organic material with concentration ranging from about 90% to about 99% and increases progressively. As shown in FIG. 8, the first material layer comprises the first conductive material with concentration ranging from about 1% to about 10% and both interfaces have a lower concentration with a spatial distribution. The first material layer comprises the organic material with concentration ranging from about 90% to about 99% and both interfaces have a higher concentration with a spatial distribution. In FIG. 6 to FIG. 8, the first conductive material that comprises metal and the first material layer has a concentration with a spatial distribution. If the first conductive material uses metal oxide or a mixture of metal and metal oxide as material, the concentration range may be adjusted depending on hole injection efficiency.

The hole injection structure of the present invention uses a mixture of metal or metal oxide and organic material as a part of the hole injection structure. This may effectively increase the hole concentration and hole transport rate, and therefore reduce driving voltage of the organic electroluminescence device. The material, the mixture ratio of the first conductive material and the organic material, and the substance of the second conductive material may be adjusted depending on different substances of the anode, the hole transport layer, or the organic luminescence layer to apply to interfaces of different work functions.

In summary, the hole injection structure of the organic electroluminescence device of the present invention may reduce driving voltage effectively and increase hole concentration and hole transport rate. In addition, this may perform well in interfaces of different work functions.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An organic electroluminescence device, comprising:
at least one anode disposed on a substrate;
at least one hole injection structure comprising at least one first material layer and at least one second material layer disposed on the anode, wherein the first material layer comprises a mixture of at least one first conductive material and at least one organic material, and the second material layer comprises at least one second conductive material;
at least one organic luminescence layer disposed on the hole injection structure; and
at least one electron source layer disposed on the organic luminescence layer.

2. The organic electroluminescence device of claim 1, wherein the mixture of the first conductive material and the organic material included in the first material layer has a substantially uniform concentration.

3. The organic electroluminescence device of claim 1, wherein the mixture of the first conductive material and the organic material included in the first material layer has a concentration with a spatial distribution.

4. The organic electroluminescence device of claim 1, wherein the first conductive material comprises a metal, a metal oxide, or combinations thereof.

5. The organic electroluminescence device of claim 1, wherein the first conductive material comprises a metal, and the mixture of the first material layer comprises the metal with concentration ranging from about 1% to about 10%, and the organic material with concentration ranging from about 90% to about 99%.

6. The organic electroluminescence device of claim 1, wherein the first conductive material comprises a metal, and the mixture of the first material layer comprises the metal with concentration of about 5% and the organic material with concentration of about 95%.

7. The organic electroluminescence device of claim 1, wherein the first conductive material comprises a metal that has a work function of more than about 4 eV.

8. The organic electroluminescence device of claim 1, wherein the first conductive material comprises a metal oxide, and the mixture of the first material layer comprises the metal oxide with concentration ranging from about 1% to about 10% and the organic material with concentration ranging from about 90% to about 99%.

9. The organic electroluminescence device of claim 1, wherein the first conductive material comprises a metal oxide, and the mixture of the first material layer comprises the metal oxide with concentration ranging from about 10% to about 30% and the organic material concentration ranging from about 70% to about 90%.

10. The organic electroluminescence device of claim 1, wherein the organic material of the first material layer comprises N,N′-bis-(1-naphtyl)-N,N′-diphenyl-1,1′-biphenyl-4,4′-diamine (NPB), polyethylene dioxythiophene/polystyrene sulfonate (PEDOT:PSS), 4,4′,4″-tris(3-methylphenylphenylamino) triphenylamine (m-MTDATA), or polyabuline.

11. The organic electroluminescence device of claim 1, wherein the second conductive material comprises a metal, a metal oxide, or combinations thereof.

12. The organic electroluminescence device of claim 1, wherein the second conductive material comprises tungsten oxide, praseodymium oxide, vanadium oxide, or molybdenum oxide.

13. The organic electroluminescence device of claim 1, further comprising at least one hole transport layer disposed between the organic luminescence layer and the hole injection structure.

14. The organic electroluminescence device of claim 1, further comprising at least one electron injection layer, wherein the electron source layer comprises at least one cathode and at least one electron transport layer disposed between the organic luminescence layer and the cathode, and the electron injection layer is disposed between the electron transport layer and the cathode.

15. A method of manufacturing an organic electroluminescence device, comprising:
forming at least one anode on a substrate;
forming at least one hole injection structure on the anode, the hole injection structure comprising at least one first material layer and at least one second material layer, wherein the first material layer comprises a mixture of at least one first conductive material and at least one organic material, and the second material layer comprises at least one second conductive material;
forming at least one organic luminescence layer on the hole injection structure; and
forming at least one electron source layer on the organic luminescence layer.

16. The method of claim 15, further comprising forming at least one hole transport layer between the organic luminescence layer and the hole injection structure.

17. The method of claim 15, wherein the electron source layer comprises at least one cathode and at least one electron transport layer formed between the organic luminescence layer and the cathode.

18. The method of claim 17, further comprising a step of forming at least one electron injection layer between the electron transport layer and the cathode.

19. The method of claim 15, wherein the first conductive material comprises a metal, a metal oxide, or combinations thereof.

20. The method of claim 15, wherein the first conductive material comprises a metal, and the mixture of the first material layer comprises the metal with concentration ranging from about 1% to about 10%, and the organic material with concentration ranging from about 90% to about 99%.

21. The method of claim 15, wherein the first conductive material comprises a metal, and the mixture of the first material layer comprises the metal with concentration of about 5% and the organic material with concentration of about 95%.

22. The method of claim 15, wherein the first conductive material comprises a metal that has a work function of more than about 4 eV.

23. The method of claim 15, wherein the first conductive material comprises a metal oxide, and the mixture of the first material layer comprises the metal oxide with concentration ranging from about 1% to about 10% and the organic material with concentration ranging from about 90% to about 99%.

24. The method of claim 15, wherein the first conductive material comprises a metal oxide, and the mixture of the first material layer comprises the metal oxide with concentration ranging from about 10% to about 30% and the organic material concentration ranging from about 70% to about 90%.

25. The method of claim 15, wherein the organic material of the first material layer comprises N,N′-bis-(1-naphtyl)-N,N′-diphenyl-1,1′-biphenyl-4,4′-diamine (NPB), polyethylene dioxythiophene/polystyrene sulfonate (PEDOT:PSS), 4,4′,4″-tris(3-methylphenylphenylamino) triphenylamine (m-MTDATA), or polyabuline.

26. The method of claim 15, wherein the second conductive material comprises a metal, a metal oxide, or combinations thereof.

27. The method of claim 15, wherein the second conductive material comprises tungsten oxide, praseodymium oxide, vanadium oxide, or molybdenum oxide.

28. The method of claim 15, wherein the mixture of the first conductive material and the organic material included in the first material layer has a substantially uniform concentration.

29. The method of claim 15, wherein the mixture of the first conductive material and the organic material included in the first material layer has a concentration with a spatial distribution.

30. A hole injection structure, comprising:
at least one first material layer comprising a mixture of at least one first conductive material and at least one organic material; and
at least one second material layer comprising at least one second conductive material.

31. The hole injection structure of claim 30, wherein the mixture of the first conductive material and the organic material included in the first material layer has a substantially uniform concentration.

32. The hole injection structure of claim 30, wherein the mixture of the first conductive material and the organic material included in the first material layer has a concentration with a spatial distribution.

33. The hole injection structure of claim 30, wherein the first conductive material comprises a metal, a metal oxide, or combinations thereof.

34. The hole injection structure of claim 30, wherein the first conductive material comprises a metal, and the mixture of the first material layer comprises the metal with concentration ranging from about 1% to about 10%, and the organic material with concentration ranging from about 90% to about 99%.

35. The hole injection structure of claim 30, wherein the first conductive material comprises a metal, and the mixture of the first material layer comprises the metal with concentration of about 5% and the organic material with concentration of about 95%.

36. The hole injection structure of claim 30, wherein the first conductive material comprises a metal that has a work function of more than about 4 eV.

37. The hole injection structure of claim 30, wherein the first conductive material comprises a metal oxide, and the mixture of the first material layer comprises the metal oxide with concentration ranging from about 1% to about 10% and the organic material with concentration ranging from about 90% to about 99%.

38. The hole injection structure of claim 30, wherein the first conductive material comprises a metal oxide, and the mixture of the first material layer comprises the metal oxide with concentration ranging from about 10% to about 30% and the organic material concentration ranging from about 70% to about 90%.

39. The hole injection structure of claim 30, wherein the organic material of the first material layer comprises N,N′-bis-(1-naphtyl)-N,N′-diphenyl-1,1′-biphenyl-4,4′-diamine (NPB), polyethylene dioxythiophene/polystyrene sulfonate (PEDOT:PSS), 4,4′,4″-tris(3-methylphenylphenylamino) triphenylamine (m-MTDATA), or polyabuline.

40. The hole injection structure of claim 30, wherein the second conductive material comprises a metal, a metal oxide, or combinations thereof.

41. The hole injection structure of claim 30, wherein the second conductive material comprises tungsten oxide, praseodymium oxide, vanadium oxide, or molybdenum oxide.
